(19) United States
(12) Patent Application Publication
(10) Pub. No.: US 2026/0013061 A1
(43) Pub. Date: Jan. 8, 2026

(54) EXTERNAL MODULE

(71) Applicant: ASUSTeK COMPUTER INC., Taipei City (TW)

(72) Inventors: Hsiang-An Chou, Taipei City (TW); Chien-Ying Chen, Taipei City (TW)

(73) Assignee: ASUSTeK COMPUTER INC., Taipei City (TW)

(21) Appl. No.: 18/800,121

(22) Filed: Aug. 11, 2024

(30) Foreign Application Priority Data
Jul. 2, 2024 (TW) 113124638

(51) Int. Cl. H05K 7/14

(52) U.S. Cl. CPC H05K 7/1407

(57) ABSTRACT

An external module is suitable for an electronic device. The external module includes a main body with an external housing, a first circuit board, a locking component and a connector. The first circuit board is disposed on the external housing in a first direction. The first circuit board has a first through hole and at least one electrical point is formed on one side of the first circuit board. The locking component is passed through the first through hole along a second direction and is securely disposed on the housing. The hole diameter of the first through hole is larger than the outer diameter of the locking component. The connector is disposed on a surface of the electronic device and aligned with the at least one electrical contact.

### CROSS-REFERENCE TO RELATED APPLICATION

This application claims the priority benefit of Taiwan application serial no. 113124638, filed on Jul. 2, 2024. The entirety of the above-mentioned patent application is hereby incorporated by reference herein and made a part of this specification.

### BACKGROUND

### Technical Field

The disclosure relates to an external module, and in particular to an external module used in an electronic device.

### Description of Related Art

The existing external components (network cards, graphics cards, hard drives or memories) used in electronic devices such as servers have assembly tolerances. As a result, the circuit board of the external component is unable to be accurately plugged into the connection port of the electronic device, and causes the problems such as poor contact or structural damage. Taking the existing circuit board and connection port as an example, the gap size is much smaller than the tolerance size of the general structure. When combining multiple assembly structures, the tolerance of each structure needs to be reduced to a smaller size, using more positioning structures and control the size or using special assembly techniques (such as: insert the circuit board first and then lock the screws or leave all the screws unlocked and lock them in the fixed locking sequence after the assembly is completed) to eliminate the aforementioned problems that cannot be installed accurately, but the problems invisibly increases production costs, control costs and quality costs.

### SUMMARY

The external module of the disclosure suitable for an electronic device, the external module includes a main body, a first circuit board, a locking component, and a connector. The main body has a housing. The first circuit board is disposed on the housing along a first direction. The first circuit board has a first through hole, and one side of the first circuit board has at least one electrical contact. The locking component is passed through the first through hole along a second direction and is securely disposed on the housing. A hole diameter of the first through hole is larger than an outer diameter of the locking component. The connector is disposed on a surface of the electronic device and aligned with the at least one electrical contact. When the external module is moved toward the electronic device along the first direction, the first circuit board is adapted to be moved relative to the locking component to plug in the connector.

Based on the foregoing, the external module of the disclosure includes a main body, a first circuit board and a locking component. The locking component positions the first circuit board on the housing of the main body, and the first circuit board is adapted to move in three axes (up and down, left and right, front and rear) relative to the locking component to correctly align the circuit board to the connector, then apply an external force to plug the circuit board into the connector. Compared with the fixed-point locking method of existing external components, the hole diameter of the first through hole of the first circuit board of the disclosure is larger than the outer diameter of the locking component, so that it has the function of fine-tuning the orientation to improve the tolerance problems of existing external components and the defects such as inability to accurately plug into the connector, other problems such as poor contact or structural damage can also be avoided.

Several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic three-dimensional view of an external module combined with an electronic device according to an embodiment of the disclosure.

FIG. 1B is a schematic three-dimensional view of the first circuit board plugging into the connector of FIG. 1A.

FIG. 1C is a schematic three-dimensional view of the external module of FIG. 1A.

FIG. 1D is a schematic three-dimensional view of the external module from another angle of FIG. 1C.

FIGS. 2A and 2B are schematic view of the plugging process between the external module and the electronic device in FIG. 1A.

FIG. 2C is an exploded schematic view of the locking component of FIG. 2A.

FIG. 3A is a schematic side view of the external module and electronic device using a locking component according to another embodiment of FIG. 1A.

FIG. 3B is an exploded schematic view of the locking component of FIG. 3A.

### DESCRIPTION OF THE EMBODIMENTS

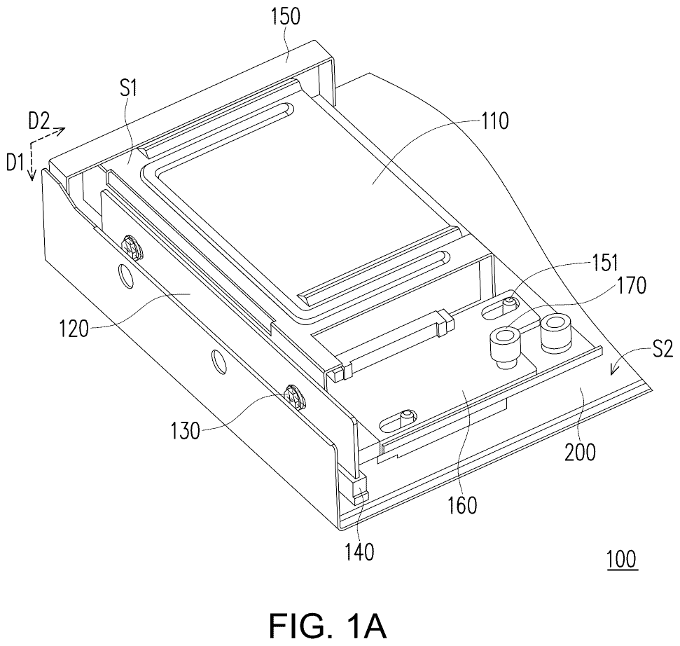

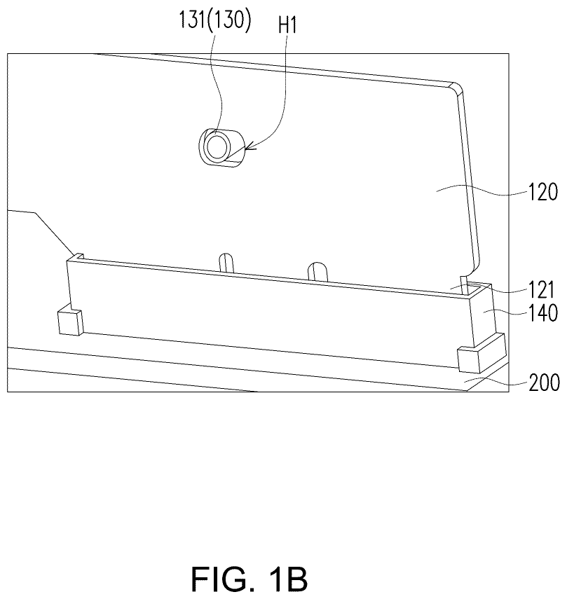

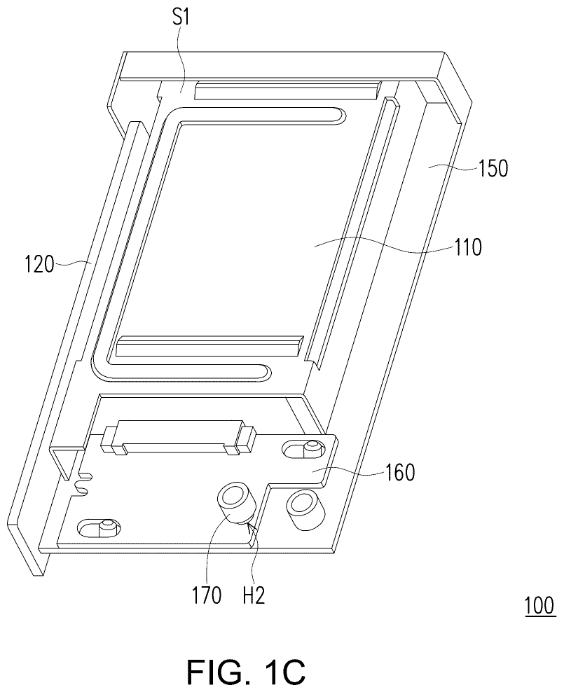

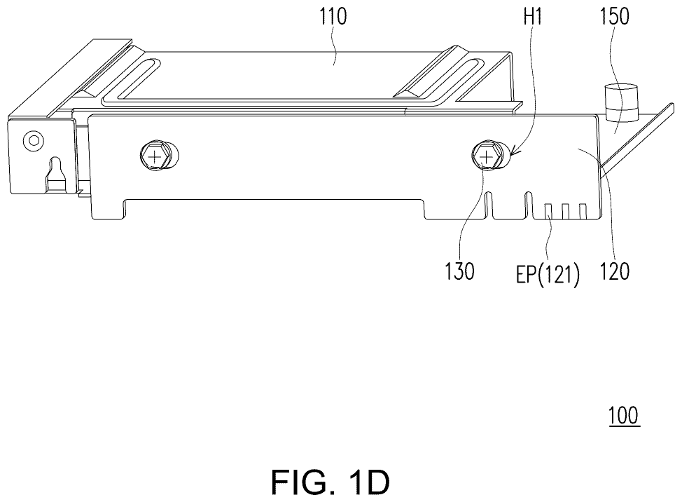

FIG. 1A is a schematic three-dimensional view of an external module combined with an electronic device according to an embodiment of the disclosure. FIG. 1B is a schematic three-dimensional view of the first circuit board plugging into the connector of FIG. 1A. FIG. 1C is a schematic three-dimensional view of the external module of FIG. 1A. FIG. 1D is a schematic three-dimensional view of the external module from another angle of FIG. 1C.

With reference to FIG. 1A to FIG. 1D, the external module 100 of this embodiment is suitable for an electronic device 200 (such as a desktop computer, a game console, a server or other similar electronic devices), and the external module 100 is, for example, a network card, a display card, Hard drive, memory or other similar electronic components.

The external module 100 includes a main body 110, a first circuit board 120, a locking component 130, and a connector 140.

The main body 110 is a rectangular structure and has a housing S1. The first circuit board 120 is disposed on the housing S1 of the main body 110 along a first direction D1. The first circuit board 120 has a first through hole H1 and one side of the first circuit board 120 has at least one electrical contact EP (see FIG. 1D).

The locking component 130 is passed through the first through hole H1 of the first circuit board 120 along a second direction D2 and is fixed on the housing S1 to limit the first circuit board 120 to one side of the main body 110 and the first circuit board 120 spaced apart from the housing S1. A hole diameter of the first through hole H1 is larger than an outer diameter of the locking component 130. The connector 140 is disposed on a surface S2 of the electronic device 200 and is aligned with the at least one electrical contact EP of the first circuit board 120.

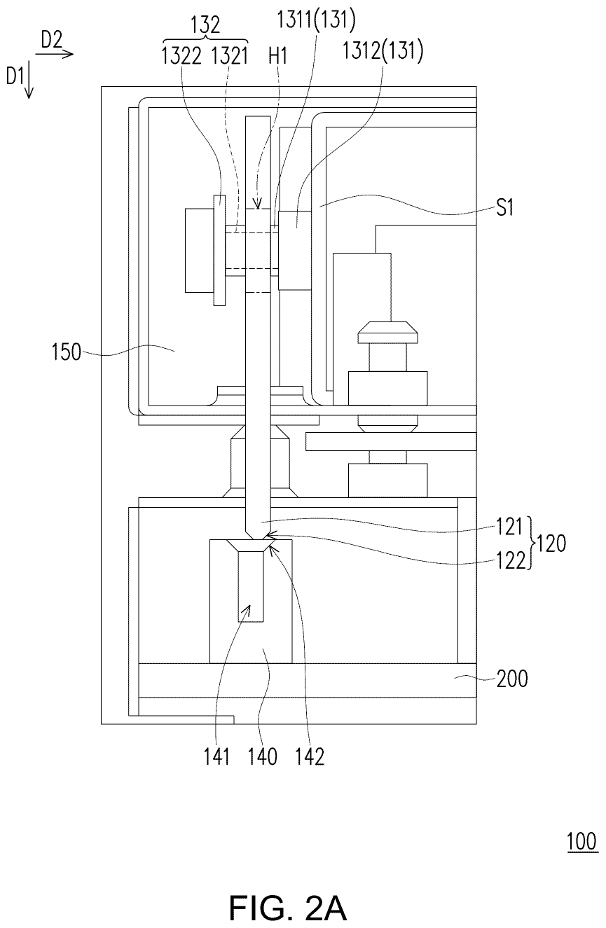

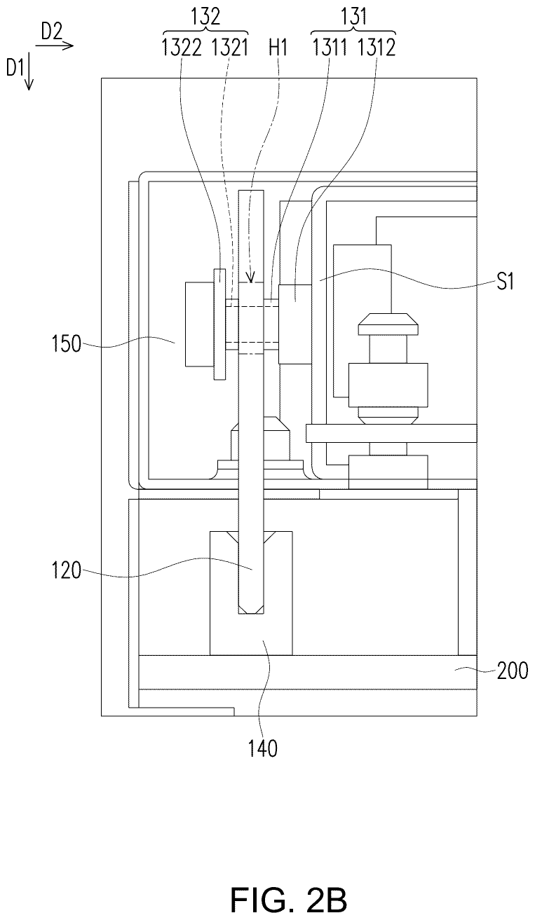

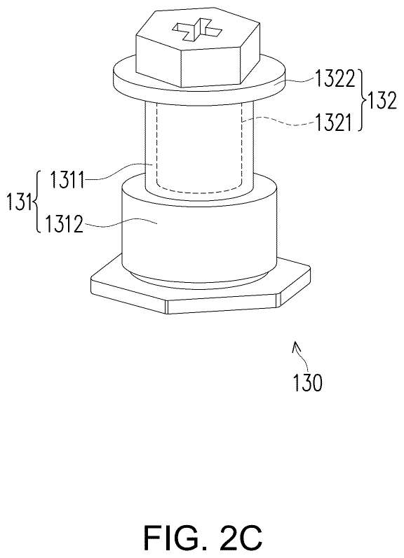

FIGS. 2A and 2B are schematic view of the plugging process between the external module and the electronic device in FIG. 1A. FIG. 2C is an exploded schematic view of the locking component of FIG. 2A.

With reference to FIG. 1B to FIG. 1D and FIG. 2A to FIG. 2B, when the external module 100 is moved toward the electronic device 200 along the first direction D1, the first circuit board 120 is adapted to be moved relative to the locking component 130 in three axes (front and back, left and right, and up and down) for alignment and plugging in the connector 140 with the at least one electrical contact EP.

With reference to FIGS. 2A to 2C, the locking component 130 includes a stepped stud 131 and a screw 132. The stepped stud 131 is fixed on the shell S1 of the main body 110 and an extending part 1311 of the stepped stud 131 passed through the first through hole H1 of the first circuit board 120. The threaded part 1321 of the screw 132 is screwed into the extending part 1311 of the stepped stud 131.

The stepped stud 131 has a stopper 1312. The outer diameter of the stopper 1312 is larger than the hole diameter of the first through hole H1 and the stopper 1312 is spaced from one side of the first circuit board 120. The screw 132 has a gasket 1322, an outer diameter of the gasket 1322 is larger than the hole diameter of the first through hole H1 and the gasket 1322 is spaced from the other side of the first circuit board 120, thereby limiting the first circuit board 120 between the stepped stud 131 and the screw 132.

With reference to FIGS. 1D, 2A and 2B, in detail, the outer diameter of the stopper 1312 and the gasket 1322 is greater than the hole diameter of the first through hole H1, and the hole diameter of the first through hole H1 is greater than the outer diameter of the extending part 1311 and the threaded part 1321, after the threaded part 1321 is screwed to the extending part 1311, the first through hole H1 of the first circuit board 120 is suitable for moving forward and backward along the extending part 1311, or the first through hole H1 is suitable for moving up and down or moving left and right relative to the extending part 1311.

With reference to FIG. 2B, after the first circuit board 120 is plugged in the connector 140, the extending part 1311 of the stepped stud 131 is abutted a lower edge of the first through hole H1 to limit the first circuit board 120 to avoid the first circuit board 120 from being ejected when suffering an external force.

Referring to FIGS. 2A and 2B, the first circuit board 120 has a plug portion 121 and two first chamfers 122. The plug portion 121 is extended from the bottom of the first circuit board 120 toward the connector 140, and a first circuit is formed on the outer surface of the plug portion 121. The two first chamfers 122 are formed oppositely on one end of the plug portion 121. The angles of the two first chamfers 122 can be the same or different, and the angles can be adjusted according to needs. The angle is not limited in the disclosure. In addition, at least one electrical contact EP includes a plurality of electrical contacts EP and the electrical contacts EP are disposed on the corresponding plug portion 121.

The connector 140 includes a slot 141 and two second chamfers 142. The inner diameter of the slot 141 is matched the outer diameter of the plug portion 121, and a second circuit is formed on the inner surface of the slot 141. Two second chamfers 142 are formed oppositely on the inner wall of the slot 141 and located at a top of the connector 140. The angles of the two second chamfers 142 can be the same or different, and the angles can be adjusted according to needs. The angle is not limited in the disclosure.

Referring to FIG. 2A, the external module 100 is located above the electronic device 200, and the plug portion 121 of the first circuit board 120 is misaligned with the slot 141 of the connector 140. At the same time, one of first chamfers 122 of the first circuit boards 120 is aligned with one of the second chamfers 142 of the connector 140. Referring to FIGS. 2A and 2B, then pressing down the external module 100, so that one of the first chamfers 122 of the first circuit board 120 contacts one of the second chamfers 142 of the connector 140, and one of the first chamfers 122 is moved along one of the second chamfers 142 to drive the plug portion 121 into the slot 141, thus the second circuit of the slot 141 is coupled to the first circuit of the plug portion 121.

In addition, when the plug portion 121 of the first circuit board 120 is abutted the slot 141 of the connector 140, the first circuit board 120 is moved along the stepped stud 131 toward the screw 132 with the first through hole H1, and guided by the first chamfers 122 and the second chamfers 142 to finally accurately align the plug portion 121 to the slot 141. In short, the first circuit board 120 utilizes the three-axis movement characteristics relative to the locking component 130 so that the first circuit board 120 can be guided to the correct position for plugging in the connector 140.

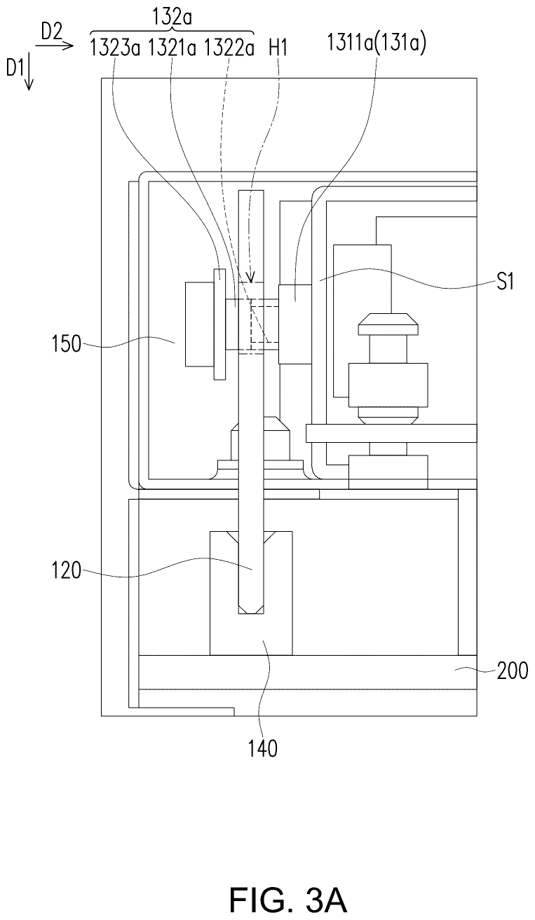

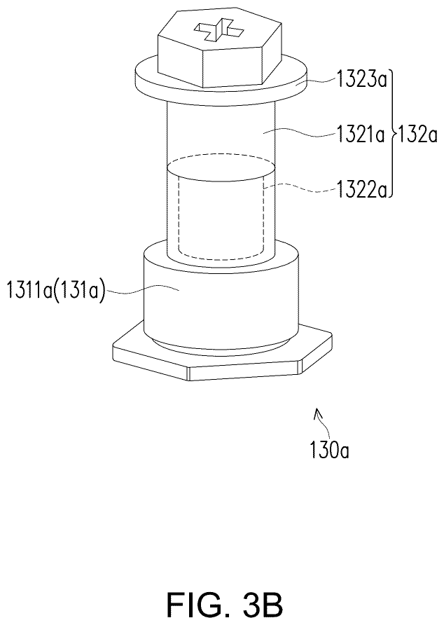

FIG. 3A is a schematic side view of the external module and electronic device using a locking component according to another embodiment of FIG. 1A. FIG. 3B is an exploded schematic view of the locking component of FIG. 3A.

Referring to FIG. 3A and FIG. 3B, the locking component 130a of this embodiment includes a stud 131a and a step screw 132a. The stud 131a is fixed to the main body, and the step screw 132a is screwed to the stud 131a. An extending portion 1321a of the step screw 132a is passed through the first through hole H1 of the first circuit board 120, and the thread portion 1322a of the step screw 132a is formed on the extending portion 1321a and is screwed to the stud 131a.

After the first circuit board is plugged in the connector, the extending portion 1321a of the stud 131a and the step screw 132a are abutted the lower edge of the first through hole H1 to limit the first circuit board. In addition, the stud 131a has a stopper 1311a. The outer diameter of the stopper 1311a is larger than the hole diameter of the first through hole H1 and the stopper 1311a is spaced from one side of the first circuit board 120. The step screw 132a includes a gasket 1323a, the outer diameter of the gasket 1323a is larger than the hole diameter of the first through hole H1 and the gasket 1323a is spaced from the other side of the first circuit board 120, thereby limiting the first circuit board 120 between the stepped screw 132a and the stud 131a.

The external module 100 further includes an outer frame 150, a second circuit board 160, and a fastener 170. The outer frame 150 accommodates the main body 110 and has a plurality of limiting posts 151, the plurality of limiting posts 151 are vertically formed on a top surface of the outer frame 150 and adjacent to the main body 110. The outer frame 150 is used to provide protection for the main body 110 and bear an external impact. The second circuit board 160 is coupled to the main body 110 and sleeved on the plurality of limiting posts 151. The fastener 170 is passed through a second through hole H2 of the second circuit board 120 and locked to the outer frame 150, thereby preventing the second circuit board 160 from shaking due to external force.

Based on the foregoing, the external module of the disclosure includes a main body, a first circuit board and a locking component. The locking component positions the first circuit board on the housing of the main body, and the first circuit board is adapted to move in three axes (up and down, left and right, front and rear) relative to the locking component to correctly align the circuit board to the connector, then apply an external force to plug the circuit board into the connector. Compared with the fixed-point locking method of existing external components, the hole diameter of the first through hole of the first circuit board of the disclosure is larger than the outer diameter of the locking component, so that it has the function of fine-tuning the orientation to improve the tolerance problems of existing external components and the defects such as inability to accurately plug into the connector, other problems such as poor contact or structural damage can also be avoided.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A external module, suitable for an electronic device, the external module comprising:
a main body, having a housing;
a first circuit board, disposed on the housing along a first direction, wherein the first circuit board has a first through hole, and one side of the first circuit board has at least one electrical contact;
a locking component, passed through the first through hole along a second direction and is securely disposed on the housing, wherein a hole diameter of the first through hole is larger than an outer diameter of the locking component; and
a connector, disposed on a surface of the electronic device and aligned with the at least one electrical contact,
wherein, when the external module is moved toward the electronic device along the first direction, the first circuit board is adapted to be moved relative to the locking component to plug in the connector.

2. The external module as recited in claim 1, wherein the locking component includes a stepped stud and a screw, the stepped stud is fixed on the main body and passed through the first through hole of the first circuit board, and the screw is screwed to the stepped stud.

3. The external module as recited in claim 2, wherein the stepped stud is abutted a lower edge of the first through hole to limit the first circuit board after the first circuit board is plugged in the connector.

4. The external module as recited in claim 2, wherein the stepped stud has a stopper, the outer diameter of the stopper is larger than the hole diameter of the first through hole, and the stopper is spaced from one side of the first circuit board, the screw has a gasket, the outer diameter of the gasket is larger than the hole diameter of the first through hole and the gasket is spaced from the other side of the first circuit board.

5. The external module as recited in claim 1, wherein the locking component includes a stud and a step screw, the stud is fixed on the main body and passed through the first through hole of the first circuit board, and the step screw is screwed to the stud.

6. The external module as recited in claim 5, wherein the stud and the stepped screw are abutted the lower edge of the first through hole to limit the first circuit board after the first circuit board is plugged in the connector.

7. The external module as recited in claim 5, wherein the stud has a stopper, the outer diameter of the stopper is larger than the hole diameter of the first through hole, and the stopper is spaced from one side of the first circuit board, the stepped screw has a gasket, the outer diameter of the gasket is larger than the hole diameter of the first through hole and the gasket is spaced from the other side of the first circuit board.

8. The external module as recited in claim 1, wherein the first circuit board has a plug portion and two first chamfers, the plug portion is extended from the bottom of the first circuit board toward the connector, and the two first chamfers are formed oppositely on one end of the plug portion.

9. The external module as recited in claim 8, wherein the connector includes a slot and two second chamfers, the inner diameter of the slot is matched the outer diameter of the plug portion, and the two second chamfers are oppositely formed on the inner wall of the slot and located on a top of the connector.

10. The external module as recited in claim 9, wherein the first chamfer is moved along one of the second chamfers to drive the plug portion into the slot.

11. The external module as recited in claim 1, further comprising an outer frame accommodating the main body and has a plurality of limiting posts, the plurality of limiting posts are vertically formed on a top surface of the outer frame and adjacent to the main body.

12. The external module as recited in claim 11, further comprising a second circuit board coupled to the main body and sleeved on the plurality of limiting posts.

13. The external module as recited in claim 12, further comprising a fastener passed through the second circuit board and locked to the outer frame.
